(19) United States
(12) Patent Application Publication
(10) Pub. No.: US 2019/0137543 A1
(43) Pub. Date: May 9, 2019

(54) TESTING APPARATUS FOR TESTING A SEMICONDUCTOR DEVICE

(71) Applicant: SAMSUNG ELECTRONICS CO., LTD., Suwon-si (KR)

(72) Inventors: Kyoung Hun Eo, Suwon-si (KR); Min Gu Kim, Yongin-si (KR); In Bong Pok, Hwaseong-si (KR)

(21) Appl. No.: 15/995,918

(22) Filed: Jun. 1, 2018

(30) Foreign Application Priority Data
Nov. 6, 2017 (KR) 10-2017-0146661

(51) Int. Cl. G01R 1/07; G01R 1/073; G01R 1/16

(52) U.S. Cl. CPC G01R 1/07; G01R 1/16; G01R 1/07342

(57) ABSTRACT

A testing apparatus includes a test head body, a test board coupled to the test head body, and a spring pin block coupled to a lower portion of the test board. The testing apparatus further includes a magnetic field generator penetrating through each of the test head body, the test board, and the spring pin block.

### CROSS-REFERENCE TO RELATED APPLICATION(S)

This application claims priority under 35 U.S.C. § 119 to Korean Patent Application No. 10-2017-0146661 filed on Nov. 6, 2017 in the Korean Intellectual Property Office, the disclosure of which is incorporated by reference herein in its entirety.

### TECHNICAL FIELD

The present inventive concept relates to a testing apparatus, and more particularly, to a testing apparatus for testing a semiconductor device.

### DISCUSSION OF RELATED ART

Semiconductor devices may be used for high-capacity data processing and are under development to have a reduced volume. Thus, increased operating rates and degrees of integration of memory devices used in semiconductor products are desired. To satisfy such demand, magnetic random access memories (MRAM), in which memory operations may be implemented using a change in resistance depending on a change in polarity of magnetic bodies, have been proposed.

A process for manufacturing semiconductor products, such as MRAMs, includes a fabrication (FAB) process of forming semiconductor devices on a wafer, an electric die sorting (EDS) process for testing electrical characteristics of respective semiconductor devices formed on the wafer, and an assembly process, in which semiconductor devices determined to be free of any defects by the EDS process are individually separated, and then, are packaged to be protected from external mechanical, physical, and chemical impacts.

The EDS process is a process for testing various electrical characteristics of semiconductor devices on the wafer using a testing apparatus, to determine whether semiconductor devices formed on the wafer are defective. In the EDS process, defective semiconductor devices may be repaired, and semiconductor devices that are impossible to repair may be removed.

### SUMMARY

According to an exemplary embodiment of the present inventive concept, a testing apparatus includes a test head body, a test board coupled the test head body, and a spring pin block coupled to a lower portion of the test board. The testing apparatus further includes a magnetic field generator penetrating through each of the test head body, the test board, and the spring pin block.

According to an exemplary embodiment of the present inventive concept, a testing apparatus includes a test head, and a magnetic field generator penetrating through the test head. The testing apparatus further includes a vertical driver attached to an upper portion of the magnetic field generator. The magnetic field generator includes a column portion penetrating through the test head, and an electromagnet mounted on a lower portion of the column portion.

According to an exemplary embodiment of the present inventive concept, a testing apparatus includes a test controller receiving and outputting electrical signals for testing of a semiconductor device. The testing apparatus further includes a test head electrically connected to the test controller, and a magnetic field generator penetrating through the test head, electrically connected to the test controller, and applying a magnetic field to the semiconductor device. The testing apparatus additionally includes a probe card provided below the test head, and including a hole and probe needles disposed adjacent to the hole. The magnetic field generator includes a protrusion having a diameter smaller than a diameter of the hole of the probe card.

According to an exemplary embodiment of the present inventive concept, testing apparatus includes a test head including a test head body, a test board disposed on a portion of the test head body, and a spring pin block disposed on a portion of the test board. The testing apparatus further includes a magnetic field generator including a column portion penetrating the test head body, the test board and the spring pin block, and an electromagnet disposed on the column portion. The electromagnet extends beyond the spring pin block.

### BRIEF DESCRIPTION OF DRAWINGS

The above and other features of the present inventive concept will become more apparent by describing in detail exemplary embodiments thereof, with reference to the accompanying drawings, in which:

FIGS. 1 to 3 are schematic diagram illustrating a testing apparatus according to an exemplary embodiment of the present inventive concept;

FIG. 4 is a circuit diagram of a semiconductor device that may be tested by a testing apparatus according to an exemplary embodiment of the present inventive concept;

FIG. 5 is a perspective view of a nonvolatile memory cell of FIG. 4 according to an exemplary embodiment of the present inventive concept;

FIGS. 6A and 6B are drawings illustrating a magnetization direction and a reading operation of a magnetoresistive device according to an exemplary embodiment of the present inventive concept; and

FIG. 7 is a diagram illustrating characteristics of a semiconductor device that may be measured by a testing apparatus according to an exemplary embodiment of the present inventive concept.

### DETAILED DESCRIPTION OF THE EMBODIMENTS

Hereinafter, example embodiments of the present inventive concept will be described as follows with reference to the accompanying drawings.

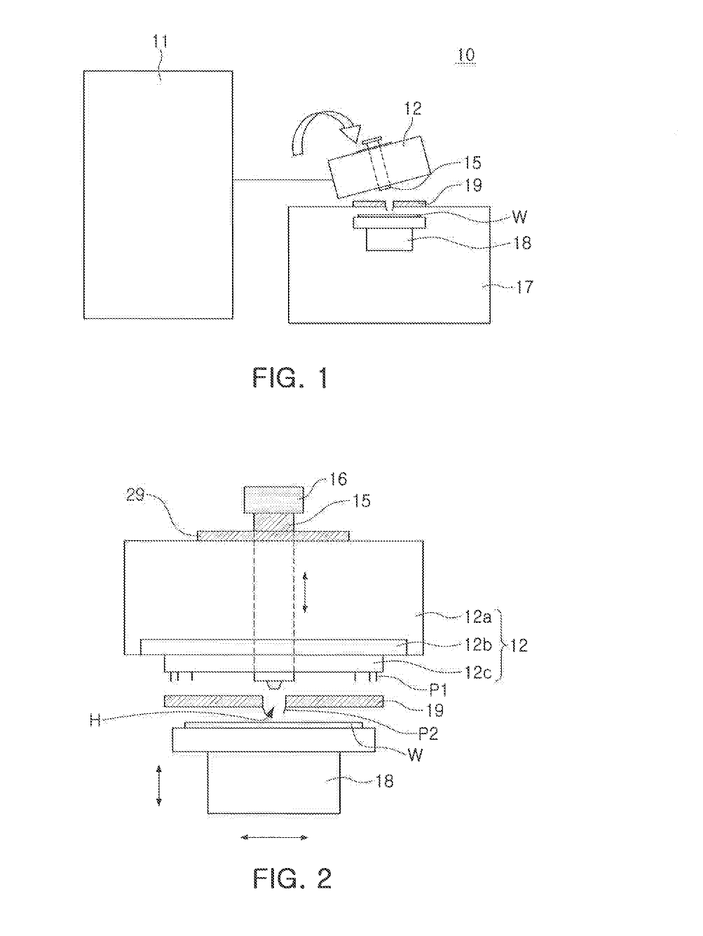

With reference to FIGS. 1 to 3, a testing apparatus 10 according to an exemplary embodiment of the present inventive concept may include a test controller 11, a test head 12, a magnetic field generator 15 and a measuring unit 17.

The measuring unit 17 provides a space in which electrical characteristics of a semiconductor device may be inspected. A probe card 19, including probe needles P2 for forming an electrical connection between the probe card 19 and the semiconductor device, may be located on an upper portion of the measuring unit 17. The probe card 19 may serve as a medium to transmit an electrical signal generated in the test controller 11 to the semiconductor device. In this case, the semiconductor device may be formed on a wafer W.

A chuck 18 supporting the wafer W may be mounted in the measuring unit 17. The chuck 18 may transfer the semiconductor device to a position in which a test is to be performed, at the time of performing a test operation. The wafer W may be provided with a plurality of semiconductor devices, and the chuck 18 may move in an upward, downward, or lateral direction, to transfer the semiconductor devices to a test position for a test operation to be performed.

The test head 12 may be electrically connected to the test controller 11, and may be coupled to the probe card 19 positioned on the measuring unit 17 during a test. For example, an electrical signal transmitted by the test controller 11 may be transmitted to the probe card 19 via the test head 12.

The test head 12 may include a test head body 12a, a test board 12b mounted on the test head body 12a, and a spring pin block 12c coupled to a lower portion of the test board 12b. For example, the test board 12b is mounted on a bottom surface of the test head body 12a, and the spring pin block 12c is mounted on a bottom surface of the test board 12b. A plurality of spring pins P1, electrically connected to the probe card 19, may be provided on a lower surface of the spring pin block 12c.

The electrical signal, generated by the test controller 11 and transmitted to the test head 12, may be transmitted to the probe card 19, by sequentially passing through the test board 12b of the test head 12 and the spring pin P1 of the spring pin block 12c of the test head 12. The electrical signal transmitted to the probe card 19 may be applied to the semiconductor device formed on the wafer W.

A test result output by the semiconductor device may be transmitted to the probe card 19 via the probe needles P2. The probe card 19 may transmit the test result to the test head 12. The test controller 11 may receive the test result from the test head 12, to store the test result therein and/or display the test result. The test controller 11 may output an electrical signal for inspection of the semiconductor device, and may receive a test result to determine whether the semiconductor device operates without a defect.

The magnetic field generator 15 may penetrate through the test head 12, may be electrically connected to the test controller 11, and may apply a magnetic field to the semiconductor device at the time of performing a test on the semiconductor device. For example, the magnetic field generator 15 may be electrically connected to the test controller 11 via the test head 12.

The test controller 11 may control an on/off operation of the magnetic field generator 15, and/or may control an intensity of a magnetic field applied by the magnetic field generator 15 or the like.

The magnetic field generator 15 may penetrate through the test head body 12a, the test board 12b, and the spring pin block 12c. The magnetic field generator 15 may include a column portion 27, which penetrates through the test head body 12a, the test board 12b and the spring pin block 12c, and an electromagnet 21 installed on a lower portion 25 of the column portion 27. For example, the electromagnet 21 may extend beyond the spring pin block 12c such that the electromagnet 21 is exposed. The electromagnet 21 may include a core and a solenoid coil wound around the core. The electromagnet 21 may be provided with a protrusion 21P formed on a lower surface thereof. For example, the core may include the protrusion 21P.

The probe card 19 provided below the test head 12 may include a hole H located in a central portion thereof, and the probe needles P2 disposed to be adjacent to the hole H. For example, the probe needles P2 are disposed on a bottom surface of the probe card 19 that is adjacent to the hole H. The protrusion 21P may have a diameter smaller than that of the hole H. The protrusion 21P may have a slanted sidewall. For example, the protrusion 21P may have a tapered shape. As an additional example, the protrusion 21P may have a truncated cone shape. The protrusion 21P may be inserted into the hole H, to apply a magnetic field at the time of performing a test on the semiconductor device.

The testing apparatus according to an exemplary embodiment of the present inventive concept may further include a vertical driver 16 installed on an upper portion of the magnetic field generator 15. For example, the vertical driver 16 may include a motor or an actuator.

The column portion 27 may include a lower portion 25 on which the electromagnet 21 is installed, and an upper portion 26 having a diameter smaller than that of the lower portion 25. A screw thread may be formed on the upper portion 26 of the column portion 27. The vertical driver 16 may rotate the column portion 27. As the column portion 27 is rotated, the magnetic field generator 15 may move in a vertical direction or move upwardly and downwardly. For example, whenever the column portion 27 rotates once, a height of the protrusion 21P may increase or decrease by about 2 mm. For example, the vertical driver 16 may control an intensity of a magnetic field applied to the semiconductor device by controlling an interval between the protrusion 21P of the magnetic field generator 15 and the wafer W. For example, the larger the interval between the protrusion 21P of the magnetic field generator 15 and the wafer W, the weaker the intensity of the magnetic field applied to the semiconductor device will be.

The magnetic field generator 15 may further include an upper support plate 29 fixed to an upper surface of the test head 12, and the upper portion 26 of the column portion 27 is coupled to the upper support plate 29. The upper support plate 29 may include a hole in which the upper portion 26 of the column portion 27 is disposed in, and an inner wall of the hole may be provided with a screw thread formed thereon.

The magnetic field generator 15 may further include a cooling unit 23 surrounding an external surface of the electromagnet 21. The cooling unit 23 may be provided as a metallic pipe through which a coolant or cooling gas flows. An inlet and an outlet of the cooling unit 23 may be externally connected via an interior of the column portion 27 of the magnetic field generator 15.

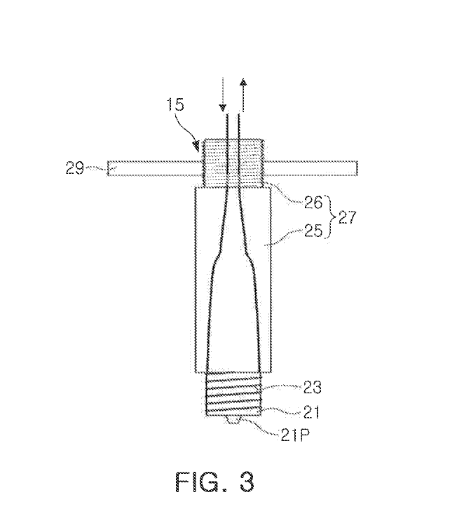

FIG. 4 is a circuit diagram of a semiconductor device that may be tested by a testing apparatus according to an exemplary embodiment of the present inventive concept.

With reference to FIG. 4, a semiconductor device 200 may include a cell array 221, a row decoder 222, a column decoder 223, a write driver 224, and a sense amplifier 225.

The cell array 221 may include a plurality of word lines WL1 to WLn, where n is a positive integer, a plurality of bit lines BL1 to BLm, where m is a positive integer, and a plurality of memory cells 100 disposed in a region where the word lines WL1 to WLn and the bit lines BL1 to BLm intersect. For example, when the memory cell 100 is implemented as a spin transfer torque magnetic resistive random access memory (STT-MRAM) cell, the memory cell 100 may include a cell transistor and a magnetoresistive device having a magnetic material.

The magnetoresistive devices may be replaced by a resistive element, such as a resistive random access memory (RRAM), using a variable resistive material such as a complex metal oxide or the like, a phase change random access memory (PRAM), using a phase change material, or the like. Materials, forming the resistive elements, may have a resistance value depending on a magnitude or a direction of a current or a voltage, and may have characteristics that a resistance value is maintained as is, even when the current or the voltage is blocked.

The row decoder 222 and the column decoder 223 may each include a plurality of switches. The row decoder 222 may be switched to provide a signal to a word line WL in response to a row address to select a word line WL. The column decoder 223 may generate column select signals CSL1 to CSLm, to select one bit line of a plurality of bit lines BL1 to BLm. The plurality of bit lines BL1 to BLm may be connected to the write driver 224. In response to a column select signal (e.g., CSL1 to CSLm), the write driver 224 may apply a current for a writing operation to the memory cell 100, of the selected bit line, in response to an external command.

At the time of reading data, a voltage applied to a bit line (e.g., BL1 to BLm) may be changed depending on a resistance of the memory cell 100. For example, when a voltage applied to the bit line is transmitted to the sense amplifier 225, the sense amplifier 225 may detect a difference between a reference voltage Vref and a bit line voltage to output a data signal.

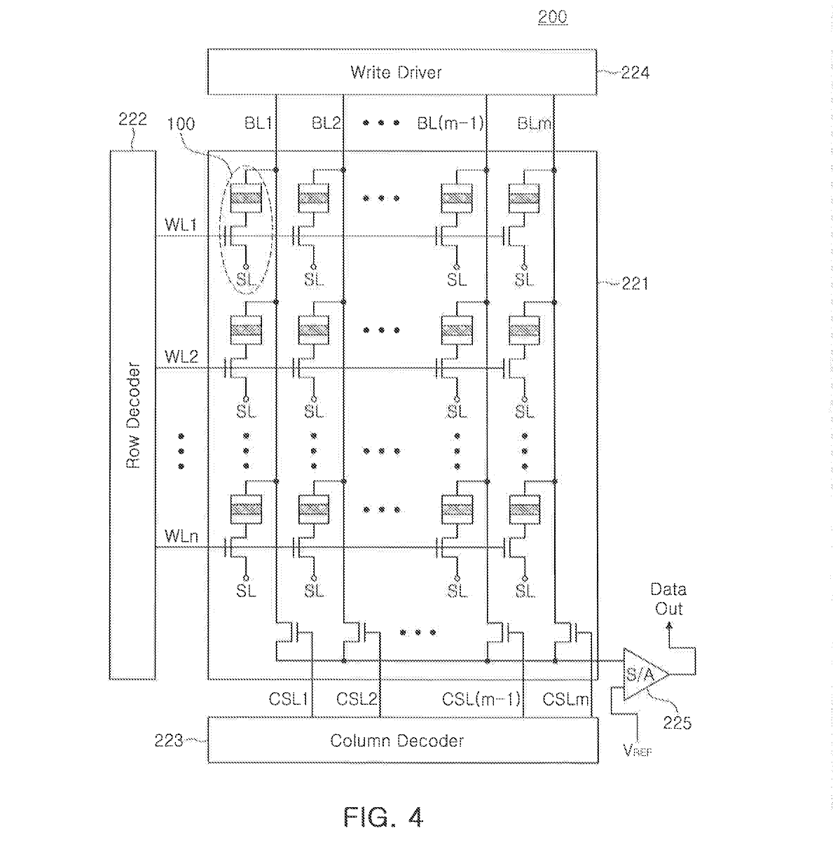

FIG. 5 is a perspective view of a nonvolatile memory cell of FIG. 4 according to an exemplary embodiment of the present inventive concept.

Referring to FIG. 5, the memory cell 100 may include a magnetoresistive device 110 and a cell transistor CT. The cell transistor CT may include a gate electrode that may be connected to the word line WL1, a first electrode that may be connected to the bit line BL1 via the magnetoresistive device 110, and a second electrode that may be connected to a source line SL.

The magnetoresistive device 110 may include a pinned layer 113, a free layer 111, and a tunnel barrier layer 112 disposed therebetween. A magnetization direction of the pinned layer 113 may be fixed, and a magnetization direction of the free layer 111 may be the same as the magnetization direction of the pinned layer 113 or may be a reverse direction hereof, depending on conditions (e.g., an applied voltage or current). For example, an anti-ferromagnetic layer may be provided to fix the magnetization direction of the pinned layer 113.

A voltage of a logic high level may be provided to the word line WL1 to turn the cell transistor CT on, and writing currents WC1 and WC2 may be applied between the bit line BL1 and the source line SL, to perform a writing operation of the STT-MRAM.

A voltage of a logic high level may be provided to the word line WL1 to turn the cell transistor CT on, and a read current may be applied in a direction from the bit line BL1 to the source line SL, to perform a reading operation of the STT-MRAM, to determine data stored in the magnetoresistive device 110 depending on a measured resistance value.

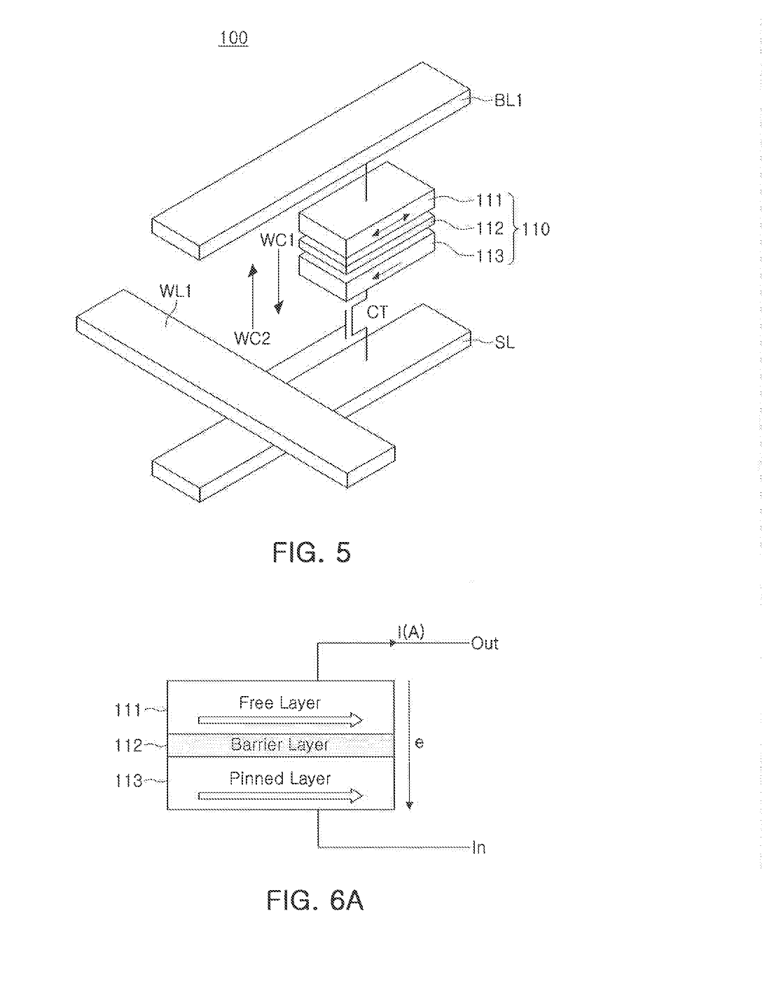

FIGS. 6A and 6B are drawings illustrating a magnetization direction and a reading operation of a magnetoresistive device according to an exemplary embodiment of the present inventive concept.

Referring to FIGS. 6A and 6B, a resistance value of a magnetoresistive device may be changed depending on a magnetization direction of the free layer 111. For example, when a read current I(A) is applied to the magnetoresistive device, a data voltage based on a resistance value of the magnetoresistive device may be output. An intensity of the read current I(A) is significantly lower than an intensity of a writing current WC, and thus, the magnetization direction of the free layer 111 might not be changed by the read current I(A).

With reference to FIG. 6A, in the case of the magnetoresistive device, the free layer 111 and the pinned layer 113 may be disposed in such a manner that a magnetization direction of the free layer 111 and a magnetization direction of the pinned layer 113 are horizontal and parallel to each other in the same direction. For example, the free layer 111 may be disposed above the pinned layer 113. As an additional example, when the read current I(A) is applied, the magnetoresistive device may have a relatively low resistance value. In this example, data may be ‘0’.

With reference to FIG. 6B, in the magnetoresistive device, the free layer 111 and the pinned layer 113 may be disposed in such a manner that a magnetization direction of the free layer ill may be horizontal and antiparallel to a magnetization direction of the pinned layer 113, for example, in an opposite direction thereto. For example, the magnetoresistive device may have a relatively high resistance value. In this example, data ‘1’ may be read by an applied current I(A).

Although FIGS. 6A and 6B illustrate that the free layer 111 and the pinned layer 113 of the magnetoresistive device 110 have horizontal magnetization directions, the free layer 111 and the pinned layer 113 may have a vertical magnetization direction in an exemplary embodiment of the present inventive concept.

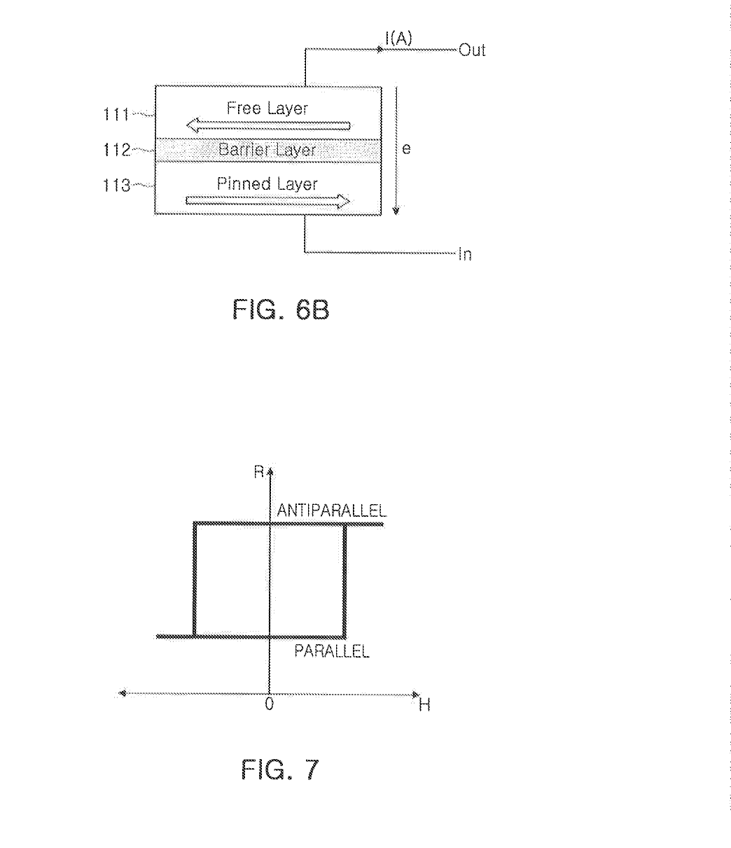

FIG. 7 is a drawing illustrating characteristics of a semiconductor device measured by a testing apparatus according to an exemplary embodiment of the present inventive concept.

A testing apparatus according to an exemplary embodiment of the present inventive concept may include the magnetic field generator 15, and thus, may measure resistance (R)-external magnetic field (H) hysteresis characteristics of the STT-MRAM. According to an exemplary embodiment of the present inventive concept, FIG. 7 illustrates an R-H hysteresis curve, switched from a parallel state to an antiparallel state and switched from an antiparallel state to a parallel state, as an example.

In the case of the R-H hysteresis curve according to an exemplary embodiment of the present inventive concept, the intensity of an external magnetic field switched from a parallel state to an antiparallel state may be substantially similar to an intensity of an external magnetic field switched from an antiparallel state to a parallel state.

As set forth above, a testing apparatus according to an exemplary embodiment of the present inventive concept may test electrical characteristics of a semiconductor device in which a magnetic field has been applied to the semiconductor device.

While the present inventive concept has been particularly shown and described with reference to exemplary embodiments thereof, it will be apparent to those of ordinary skill in the art that various changes in form and detail may be made thereto without departing from the spirit and scope of the present inventive concept.

What is claimed is:

1. A testing apparatus comprising:
a test head body;
a test board coupled to the test head body;
a spring pin block coupled to a lower portion of the test board; and
a magnetic field generator penetrating through each of the test head body, the test board, and the spring pin block.

2. The testing apparatus of claim 1, wherein the magnetic field generator comprises:
a column portion penetrating through each of the test head body, the test board, and the spring pin block; and
an electromagnet mounted on a lower portion of the column portion.

3. The testing apparatus of claim 2, further comprising a vertical driver attached to an upper portion of the magnetic field generator.

4. The testing apparatus of claim 3, wherein the column portion includes a screw thread formed on the upper portion of the column portion, and
wherein the vertical driver rotates the column portion.

5. The testing apparatus of claim 2, wherein the electromagnet comprises a core and a solenoid coil wound around the core, and
the core includes a protrusion.

6. The testing apparatus of claim 5, further comprising a probe card including a hole and probe needles disposed adjacent to the hole,
wherein a diameter of the protrusion is less than a diameter of the hole.

7. The testing apparatus of claim 5, wherein the protrusion comprises a slanted sidewall.

8. The testing apparatus of claim 2, wherein the magnetic field generator further comprises an upper support plate fixed to an upper surface of the test head body, and an upper portion of the column portion is coupled to the upper support plate.

9. The testing apparatus of claim 8, wherein the upper support plate comprises a hole in which the upper portion of the column portion is disposed, and wherein an inner wall of the hole has a screw thread.

10. The testing apparatus of claim 2, wherein the magnetic field generator further comprises a cooling unit surrounding an external surface of the electromagnet.

11. A testing apparatus comprising:
a test head;
a magnetic field generator penetrating through the test head; and
a vertical driver attached to an upper portion of the magnetic field generator,
wherein the magnetic field generator includes a column portion penetrating through the test head, and an electromagnet mounted on a lower portion of the column portion.

12. The testing apparatus of claim 11, wherein the column portion includes a screw thread formed on an upper portion of the column portion, and
wherein the vertical driver rotates the column portion.

13. The testing apparatus of claim 11, wherein the magnetic field generator comprises a test head body, a test board coupled to the test head body, and a spring pin block coupled to a lower portion of the test board, and
the column portion penetrates through the test head body, the test board, and the spring pin block.

14. The testing apparatus of claim 11, wherein the electromagnet comprises a core and a solenoid coil wound around the core, and
the core comprises a protrusion.

15. The testing apparatus of claim 14, further comprising a probe card including a hole and probe needles disposed adjacent to the hole,
wherein a diameter of the protrusion is less than a diameter of the hole.

16. The testing apparatus of claim 14, wherein the protrusion comprises a slanted sidewall.

17. The testing apparatus of claim 11, wherein the magnetic field generator further comprises an upper support plate fixed to an upper surface of the test head, and the upper portion of the column portion is coupled to the upper support plate.

18. The testing apparatus of claim 17, wherein the upper support plate comprises a hole in which the upper portion of the column portion is disposed, and wherein an inner wall of the hole has a screw thread.

19. The testing apparatus of claim 11, wherein the magnetic field generator further comprises a cooling unit surrounding an external surface of the electromagnet.

20. A testing apparatus comprising:
a test controller receiving and outputting electrical signals for testing of a semiconductor device;
a test head electrically connected to the test controller;
a magnetic field generator penetrating through the test head, electrically connected to the test controller, and applying a magnetic field to the semiconductor device; and
a probe card provided below the test head, and including a hole and probe needles disposed adjacent to the hole,
wherein the magnetic field generator includes a protrusion having a diameter smaller than a diameter of the hole of the probe card.
